(19) United States
(12) Patent Application Publication
(10) Pub. No.: US 2026/0198213 A1
(43) Pub. Date: Jul. 9, 2026

(54) DISPLAY DEVICE AND ELECTRONIC APPARATUS INCLUDING THE SAME

(71) Applicant: Samsung Display Co., Ltd., Yongin-si (KR)

(72) Inventor: JONGJANG PARK, Yongin-si (KR)

(21) Appl. No.: 19/291,883

(22) Filed: Aug. 6, 2025

(30) Foreign Application Priority Data
Jan. 7, 2025 (KR) 10-2025-0001927

(51) Int. Cl. H10K 59/80; H10K 59/122; H10K 59/38

(52) U.S. Cl. CPC H10K 59/8792; H10K 59/122; H10K 59/38

(57) ABSTRACT

A display device, includes: a substrate; a transistor on the substrate; a pixel defining layer on the transistor and exposing a sub-pixel area where light is displayed; and a color filter layer including: a light-shielding layer having an opening that exposes the sub-pixel area in a plan view; and a color filter overlapping the opening in the plan view, wherein the light-shielding layer includes: a base light-shielding layer having an inner surface that defines a portion of a boundary of the opening; and protruding light-shielding layers protruding from the inner surface of the base light-shielding layer and extending toward the sub-pixel area and defining a remaining portion of the boundary of the opening, wherein the color filter includes: a central portion overlapping the sub-pixel area; and extension portions protruding from the central portion and extending between the protruding light-shielding layers and not overlapping the sub-pixel area.

### CROSS-REFERENCE TO RELATED APPLICATIONS

The present application claims priority to and the benefit of Korean Patent Application No. 10-2025-0001927, filed on Jan. 7, 2025, in the Korean Intellectual Property Office, the entire disclosure of which is incorporated herein by reference.

### BACKGROUND

### 1. Field

Aspects of some embodiments of the present disclosure relate to a display device and an electronic apparatus including the same.

### 2. Description of the Related Art

Electronic apparatuses such as smartphones, digital cameras, laptop computers, navigation systems, and smart televisions include display devices to provide images to users. A display device generates images and provides the generated images to users through a display screen.

Developed for use in display devices have been various types of display panels, such as, for example, liquid crystal display panels and organic light-emitting display panels. Among these, the organic light-emitting display panels have a layered structure in which a substrate, a circuit layer, a display element layer, and an encapsulation layer may be sequentially stacked.

A touch panel and/or a polarizing film may be attached to the encapsulation layer of the display panel through an adhesive layer. Instead of using an adhesive layer, however, the touch panel and/or the polarizing film may be replaced with a touch sensing layer and/or a color filter layer that are/is directly formed on the encapsulation layer.

The above information disclosed in this Background section is only for enhancement of understanding of the background and therefore the information discussed in this Background section does not necessarily constitute prior art.

### SUMMARY

Aspects of some embodiments of the present disclosure relate to a display device and an electronic apparatus including the same, and for example, to a display device including a color filter layer that is directly formed on an upper portion thereof, and an electronic apparatus including the same.

Aspects of some embodiments of the present disclosure include a display device that includes a color filter layer directly formed on an upper portion thereof and has relatively improved optical characteristics. Additionally, an electronic apparatus including the display device is provided.

A display device according to some embodiments of the present disclosure may include a substrate, a transistor, a pixel defining layer, and a color filter layer. According to some embodiments, the transistor may be on the substrate. According to some embodiments, the pixel defining layer may be on the transistor and may expose a sub-pixel area where light is displayed. According to some embodiments, the color filter layer may be on the pixel defining layer and may include a light-shielding layer and a color filter. According to some embodiments, the light-shielding layer may be provided with an opening that exposes the sub-pixel area in a planar view (or a plan view). According to some embodiments, the color filter may overlap the opening in a planar view.

According to some embodiments, the light-shielding layer may include a base light-shielding layer and protruding light-shielding layers. According to some embodiments, the base light-shielding layer may include an inner surface defining a portion of a boundary of the opening in a planar view. According to some embodiments, the protruding light-shielding layers may protrude from the inner surface of the base light-shielding layer and extend toward the sub-pixel area, and may define the remaining portion of the boundary of the opening in a planar view.

According to some embodiments, the color filter may include a central portion and extension portions. According to some embodiments, the central portion may overlap the sub-pixel area in a planar view. According to some embodiments, the extension portions may protrude from the central portion and extend between the protruding light-shielding layers, and may not overlap the sub-pixel area in a planar view.

According to some embodiments of the present disclosure, in a planar view, the area of the opening may be greater than the area of the sub-pixel area.

According to some embodiments of the present disclosure, the inner surface of the base light-shielding layer may be spaced apart from the sub-pixel area in a planar view. According to some embodiments, each of the extension portions may extend to the inner surface of the base light-shielding layer.

According to some embodiments of the present disclosure, the protruding light-shielding layers may be spaced apart from each other along the inner surface of the base light-shielding layer in a planar view. According to some embodiments, the protruding light-shielding layers may be arranged at equal pitches along the inner surface of the base light-shielding layer in a planar view. According to some embodiments, the protruding light-shielding layers may have the same shape and size in a planar view. According to some embodiments, each of the protruding light-shielding layers may not overlap the sub-pixel area in a planar view. According to some embodiments, each of the protruding light-shielding layers may extend to the sub-pixel area in a planar view.

According to some embodiments of the present disclosure, the pixel defining layer may include a light-shielding material. According to some embodiments, the light-shielding material may include at least one of carbon black, carbon nanotube (CNT), or black dye.

According to some embodiments of the present disclosure, the sub-pixel area may include first sub-pixel areas, in which light of a same wavelength range may be displayed. According to some embodiments, the opening may include a first sub-opening and a second sub-opening. According to some embodiments, the first sub-opening may expose a first light-emitting region, which is one of the first sub-pixel areas, in a planar view. According to some embodiments, the second sub-opening may expose a second light-emitting region, which is another of the first sub-pixel areas, in a planar view. According to some embodiments, the first sub-opening and the second sub-opening may have the same area in a planar view.

According to some embodiments of the present disclosure, the inner surface of the base light-shielding layer may include a first sub-inner surface and a second sub-inner surface. According to some embodiments, the first sub-inner surface may define a portion of a boundary of the first sub-opening in a planar view. According to some embodiments, the second sub-inner surface may define a portion of a boundary of the second sub-opening in a planar view. According to some embodiments, the protruding light-shielding layers may include first sub-protruding light-shielding layers and second sub-protruding light-shielding layers. According to some embodiments, in a planar view, the first sub-protruding light-shielding layers may protrude from the first sub-inner surface of the base light-shielding layer and extend toward the first light-emitting region and may define the remaining portion of the boundary of the first sub-opening. According to some embodiments, in a planar view, the second sub-protruding light-shielding layers may protrude from the second sub-inner surface of the base light-shielding layer and extend toward the second light-emitting region and may define the remaining portion of the boundary of the second sub-opening.

According to some embodiments of the present disclosure, the number of first sub-protruding light-shielding layers may be different from the number of second sub-protruding light-shielding layers. According to some embodiments, the first sub-protruding light-shielding layers and the second sub-protruding light-shielding layers may have different sizes. According to some embodiments, the first sub-protruding light-shielding layers and the second sub-protruding light-shielding layers may have different shapes.

A display device according to some embodiments of the present disclosure may include a substrate, a transistor, a pixel defining layer, and a color filter layer. According to some embodiments, the transistor may be on the substrate. According to some embodiments, the pixel defining layer may be on the transistor and may expose first sub-pixel areas in each of which light of a first wavelength range is displayed. According to some embodiments, the color filter layer may be on the pixel defining layer and may include a light-shielding layer. According to some embodiments, the light-shielding layer may be provided with a first sub-opening and a second sub-opening. According to some embodiments, the first sub-opening may expose a first light-emitting region, which is one of the first sub-pixel areas, in a planar view. According to some embodiments, the second sub-opening may expose a second light-emitting region, which is another of the first sub-pixel areas, in a planar view.

According to some embodiments, the light-shielding layer may include a base light-shielding layer, first sub-protruding light-shielding layers, and second sub-protruding light-shielding layers. According to some embodiments, the base light-shielding layer may include a first sub-inner surface and a second sub-inner surface. According to some embodiments, the first sub-inner surface may define a portion of a boundary of the first sub-opening in a planar view. According to some embodiments, the second sub-inner surface may define a portion of a boundary of the second sub-opening in a planar view. According to some embodiments, in a planar view, the first sub-protruding light-shielding layers may protrude from the first sub-inner surface and extend toward the first light-emitting region and may define the remaining portion of the boundary of the first sub-opening. According to some embodiments, in a planar view, the second sub-protruding light-shielding layers may protrude from the second sub-inner surface and extend toward the second light-emitting region and may define the remaining portion of the boundary of the second sub-opening.

According to some embodiments, the first sub-opening and the second sub-opening may have the same area in a planar view. According to some embodiments, the first sub-protruding light-shielding layers and the second sub-protruding light-shielding layers may be different in terms of at least one of the number, size, or shape.

According to some embodiments of the present disclosure, the area of the first sub-opening of the base light-shielding layer may be greater than the area of the first light-emitting region in a planar view. According to some embodiments, the area of the second sub-opening of the base light-shielding layer may be greater than the area of the second light-emitting region in a planar view.

According to some embodiments of the present disclosure, the first sub-inner surface of the base light-shielding layer may be spaced apart from the first light-emitting region in a planar view. According to some embodiments, the second sub-inner surface of the base light-shielding layer may be spaced apart from the second light-emitting region in a planar view. According to some embodiments, each of the first sub-protruding light-shielding layers may extend to the first light-emitting region in a planar view. According to some embodiments, each of the second sub-protruding light-shielding layers may extend to the second light-emitting region in a planar view.

An electronic apparatus according to some embodiments of the present disclosure may include a display device. According to some embodiments, the display device may include a substrate, a transistor, a pixel defining layer, and a color filter layer. According to some embodiments, the transistor may be on the substrate. According to some embodiments, the pixel defining layer may be on the transistor and may expose sub-pixel area where light is displayed. According to some embodiments, the color filter layer may be on the pixel defining layer and may include a light-shielding layer and a color filter. According to some embodiments, the light-shielding layer may be provided with an opening that exposes the sub-pixel area in a planar view. According to some embodiments, the color filter may overlap the opening in a planar view.

According to some embodiments, the light-shielding layer may include a base light-shielding layer and protruding light-shielding layers. According to some embodiments, the base light-shielding layer may include an inner surface defining a portion of a boundary of the opening in a planar view. According to some embodiments, in a planar view, the protruding light-shielding layers may protrude from the inner surface of the base light-shielding layer and extend toward the sub-pixel area and may define the remaining portion of the boundary of the opening.

According to some embodiments, the color filter may include a central portion and extension portions. According to some embodiments, the central portion may overlap the sub-pixel area in a planar view. According to some embodiments, the extension portions may protrude from the central portion and extend between the protruding light-shielding layers, and may not overlap the sub-pixel area in a planar view.

According to some embodiments of the present disclosure, the electronic apparatus may further include a processor, a memory, and a power module. According to some embodiments, the processor may be configured to control the display device. According to some embodiments, the memory may be configured to store data necessary for the operation of the display device or the processor. According to some embodiments, the power module may be configured to generate or supply power.

According to some embodiments of the present disclosure, it may be possible to relatively improve optical characteristic variations caused by changes in the viewing angle, by allowing an opening provided in the light-shielding layer to have a greater diameter than the sub-pixel area in an area where the opening is in contact with the inner surface of the base light-shielding layer.

Moreover, it may be possible to mitigate issues related to the reflection of external light, by reducing the diameter of the opening relatively in areas where the opening is in contact with the protruding light-shielding layers.

Furthermore, by overlapping the color filter with the sub-pixel area and extending the color filter into a region between the protruding light-shielding layers, it may be possible to realize a relatively uniform display quality across the entire opening area.

### BRIEF DESCRIPTION OF THE DRAWINGS

These and/or other features will become more apparent and more readily appreciated from the following description of the embodiments, taken in conjunction with the accompanying drawings in which:

FIG. 1 is a plan view schematically illustrating a display device according to some embodiments of the present disclosure;

FIG. 2 is an enlarged view of a pixel area of the display device shown in FIG. 1;

FIG. 3 is a cross-sectional view taken along the line I-I of FIG. 2;

FIG. 4 is an enlarged view of a portion of FIG. 3 that includes the first sub-pixel area;

FIG. 5 is a cross-sectional view taken along the line II-II of FIG. 2;

FIG. 6 is a cross-sectional view taken along the line III-III of FIG. 4, showing a first color filter;

FIG. 7 is a cross-sectional view of the first color filter taken along the line IV-IV of FIG. 4;

FIG. 8 is an enlarged view of the first sub-pixel areas of FIG. 1;

FIG. 9 is a cross-sectional view taken along the line V-V of FIG. 8;

FIG. 10 is a modified example of FIG. 8;

FIG. 11 is another modified example of FIG. 8;

FIG. 12 is a block diagram of an electronic apparatus according to some embodiments of the present disclosure; and

FIG. 13 illustrates various electronic apparatuses according to some embodiments.

### DETAILED DESCRIPTION

References will now be made in detail to certain embodiments, of which examples are illustrated in the accompanying drawings, where like reference numerals refer to like elements throughout. The embodiments may have a variety of forms and permutations, but the present disclosure shall by no means be construed as being limited to the described embodiments. Rather, the present disclosure shall be construed to encompass all forms, permutations, equivalents and substitutes covered by the technical ideas and scope of the present disclosure. Accordingly, the embodiments are merely described below, by referring to the figures, to explain features of the present disclosure.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements. As such, the present disclosure shall not be restricted to the thicknesses, ratios, dimensions, etc. illustrated in the drawings.

When an element is described to be “located on,” “placed on,” “arranged on,” “connected to,” or “coupled to” another element, it shall be construed as being located on, placed on, arranged on, connected to, or coupled to the other element directly but also as possibly having another element therebetween. On the other hand, if one element is described to be “directly located on,” “directly placed on,” “directly arranged on,” “directly connected to,” or “directly coupled to” another element, it shall be construed that there is no other element interposed therebetween.

Moreover, relative terms, such as “below,” “under,” “beneath,” “lower,” “bottom,” “above,” “over,” “upper,” “top,” etc., may be used herein to describe one element's relationship to another element as illustrated in the accompanying figures. It shall be understood that relative terms are intended to encompass different orientations of the device in addition to the orientation depicted in the accompanying figures. For example, if the device in one of the figures is turned over, elements described as being on the “lower” side of the other elements would then be oriented on “upper” sides of the other elements. The term “lower” can therefore encompass an orientation of both “lower” and “upper,” depending on the particular orientation of the figure. Similarly, if the device in one of the figures is turned over, elements described as “below” or “beneath” other elements would then be oriented “above” the other elements. The term “below” or “beneath” can therefore encompass an orientation of both above and below.

Furthermore, when one device or layer is described to be “on,” “over,” “above,” and the like, another device or layer, it shall also encompass the case of yet another device or layer located on, over, above, and the like, the other device or layer or interposed between the one device or layer and the other device or layer. On the contrary, when one device or layer is described to be “directly on,” “directly over,” “directly above,” and the like, another device or layer, it shall mean that no other device or layer is interposed between the one device or layer and the other device or layer.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

Unless otherwise defined, all terms, including technical terms and scientific terms, used herein have the same meaning as how they are generally understood by those of ordinary skill in the art to which the present disclosure pertains. Any term that is defined in a general dictionary shall be construed to have the same meaning in the context of the relevant art, and, unless otherwise defined explicitly, shall not be interpreted to have an idealistic or excessively formalistic meaning.

Terms such as “first” and “second” may be used in describing various elements, but the above elements shall not be restricted to the above terms. The above terms may be used only to distinguish one element from the other. For instance, the first element may be named the second element, and vice versa, without departing the scope of claims of the present disclosure. Unless clearly used otherwise, any expressions in a singular form may include a meaning of a plural form. The term “and/or” shall include the combination of a plurality of listed items or any of the plurality of listed items.

In embodiments of the present disclosure, directions labeled as first through third directions DR1-DR3 may be defined. The first direction DR1 may be parallel to one side of a display device DD. The second direction DR2 may intersect the first direction DR1 and may be parallel to another side of the display device DD. The third direction DR3 may be perpendicular to one surface of the display device DD. In embodiments of the present disclosure, the phrase “in a plan view” refers to viewing along the third direction DR3.

FIG. 1 is a plan view schematically illustrating a display device according to some embodiments of the present disclosure. Referring to FIG. 1, a display device DD according to some embodiments of the present disclosure may serve as an image display device and may have a display area DA and a non-display area NDA defined therein.

For the sake of understanding, in FIG. 1, the boundary between the display area DA and the non-display area NDA is indicated by dotted lines. The display area DA is an area where images are displayed, whereas the non-display area NDA is an area surrounding the display area DA where images are not displayed. In some embodiments, the non-display area NDA may be omitted.

According to some embodiments, the display area DA is shown as having a rectangular shape, and the non-display area NDA is shown as surrounding the display area DA. However, the display area DA and the non-display area NDA are not necessarily limited to these specific shapes, and their configurations may vary depending on design requirements.

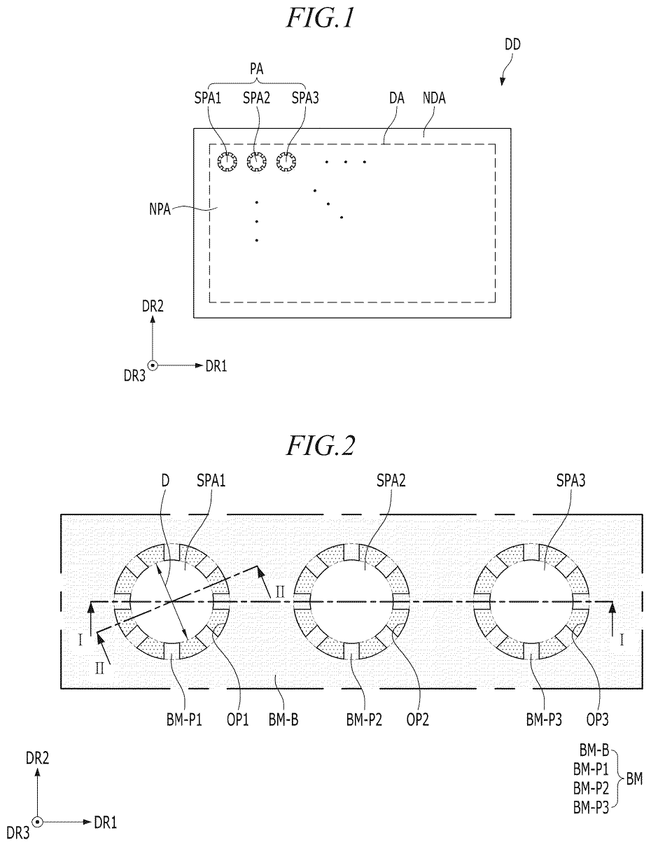

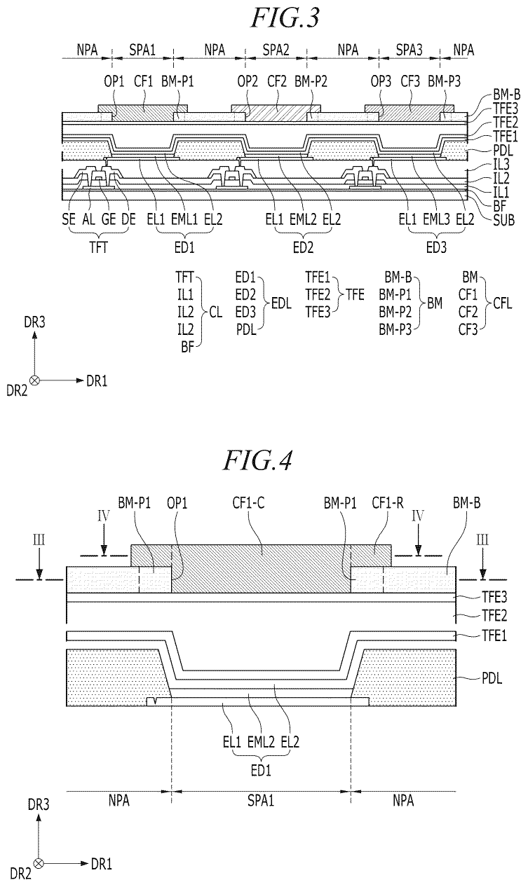

FIG. 2 is an enlarged view of a pixel area shown FIG. 1, and FIG. 3 is a cross-sectional view taken along the line I-I of FIG. 2. For the sake of clarity, color filters CF1, CF2, CF3 shown in FIG. 3 are omitted in FIGS. 1 and 2. Additionally, the boundaries of the sub-pixel areas SPA1, SPA2, SPA3, as well as the boundary between a base light-shielding layer BM-B and protruding light-shielding layers BM-P1, BM-P2, BM-P3, are indicated with dotted lines.

Referring to FIGS. 1 to 3, the display area DA may have pixel areas PA and a non-emitting area NPA defined therein. Each of the pixel areas PA may include sub-pixel areas SPA1, SPA2, SPA3. The sub-pixel areas SPA1, SPA2, SPA3 may be regions that overlap with light-emitting diodes ED1, ED2, ED3 in a planar view (or a plan view) and where the light emitted from the light-emitting diodes ED1, ED2, ED3 is displayed. The non-emitting area NPA may be defined between the sub-pixel areas SPA1, SPA2, SPA3 and may correspond to a pixel defining layer PDL in a planar view. The sub-pixel areas SPA1, SPA2, SPA3 may be defined as areas where a top surface of a first electrode EL1 is exposed by the pixel defining layer PDL, which may also define the boundaries of the sub-pixel areas SPA1, SPA2, SPA3.

As an unrestricted example, the sub-pixel areas SPA1, SPA2, SPA3 may include first sub-pixel areas SPA1, second sub-pixel areas SPA2, and third sub-pixel areas SPA3. Each of the first sub-pixel areas SPA1 may be configured to display light emitted from a first light-emitting diode ED1, each of the second sub-pixel area SPA2 may be configured to display light emitted from a second light-emitting diode ED2, and each of the third sub-pixel area SPA3 may be configured to display light emitted from a third light-emitting diode ED3.

The light-emitting diodes ED1, ED2, ED3 may be configured to emit light of different colors. For example, the first light-emitting diode ED1 may be configured to emit red light, the second light-emitting diode ED2 may be configured to emit green light, and the third light-emitting diode ED3 may be configured to emit blue light. However, the disclosure is not limited to this configuration.

Each of the first to third sub-pixel areas SPA1, SPA2, SPA3 may be provided in plurality and may be repeatedly arranged in a predetermined pattern within the display area DA. For example, the first to third sub-pixel regions SPA1, SPA2, SPA3 may be arranged in a stripe arrangement pattern, a Pentile™ arrangement pattern, or a diamond pixel™ arrangement pattern.

Each of the first to third sub-pixel areas SPA1, SPA2, SPA3 may also have various shapes in a planar view. While each of the first to third sub-pixel areas SPA1, SPA2, SPA3 is illustrated as circular in the drawings, this is merely an example and may also be elliptical, rectangular, polygonal, or other shapes.

The areas of the first to third sub-pixel areas SPA1, SPA2, SPA3 are shown as having the same size in the drawings, but this is also exemplary, and the sub-pixel areas may have different sizes.

The display device DD may include a substrate SUB, a circuit layer CL, a display element layer EDL, an encapsulation layer TFE, and a color filter layer CFL. The substrate SUB may provide a base surface on which the circuit layer CL is located. The substrate SUB may include a material such as glass, ceramic, metal, or polymer resins such as polyimide. However, the disclosure is not limited thereto, and the substrate SUB may be an inorganic layer, an organic layer, or a composite material layer and may be constituted with a single layer or multiple layers.

The circuit layer CL may be located on the substrate SUB. The circuit layer CL may include transistors TFT, a first insulating layer IL1, a second insulating layer IL2, and a third insulating layer IL3. In some embodiments, the circuit layer CL may further include a buffer layer BF.

Each of the transistors TFT may be configured to apply an electrical signal to each of the light-emitting diodes ED1, ED2, ED3. Each of the transistors TFT may include an active layer AL, which is a semiconductor pattern, a gate electrode GE, and source and drain electrodes SE, DE that are electrically connected to the active layer AL.

The first insulating layer IL1 may be located on the substrate SUB and may cover the active layer AL. The second insulating layer IL2 may be located on the first insulating layer IL1 and may cover the gate electrode GE. The third insulating layer IL3 may be located on the second insulating layer IL2 and may cover the source electrode SE and the drain electrode DE. Each of the first to third insulating layers IL1, IL2, IL3 may be an inorganic layer or an organic layer.

The buffer layer BF may be located between the substrate SUB and the first insulating layer IL1. The buffer layer BF may provide a modified surface to enhance the adhesion of the semiconductor pattern. The buffer layer BF may be an inorganic layer containing at least one of silicon nitride, silicon oxide, or silicon oxynitride.

The display element layer EDL may be located on the circuit layer CL. The display element layer EDL may include the light-emitting diodes ED1, ED2, ED3 and the pixel defining layer PDL.

Each of the light-emitting diodes ED1, ED2, ED3 may include a first electrode EL1, a light-emitting layer EML1, EML2, EML3 and a second electrode EL2. In some embodiments, a hole function layer may be provided between the first electrode EL1 and the light-emitting layer EML1, EML2, EML3 and an electron function layer may be provided between the light-emitting layer EML1, EML2, EML3 and the second electrode EL2. However, the disclosure is not limited thereto, and depending on the polarity of the first electrode EL1 and the second electrode EL2, the positions of the hole function layer and the electron function layer may be interchanged.

The pixel defining layer PDL may be located on the circuit layer CL and may cover the regions between the first electrodes EL1 in a planar view. The pixel defining layer PDL may be located to correspond to the non-emitting area NPA. The sub-pixel areas SPA1, SPA2, SPA3 may be exposed by the pixel defining layer PDL. The pixel defining layer PDL may be provided with openings that expose the sub-pixel areas SPA1, SPA2, SPA3, which may be defined as areas where a top surface of the first electrode EL1 is exposed by the pixel defining layer PDL.

The pixel defining layer PDL may include at least one organic insulating material selected from the group consisting of polyimide, polyamide, acrylic resin, benzocyclobutene, and phenol resin. The pixel defining layer PDL may include a light-shielding material. The light-shielding material may include at least one of carbon black, carbon nanotube (CNT), or black dye. According to some embodiments, a conventional polarizing film may be replaced by the pixel defining layer PDL, which includes a light-shielding material, and the color filter layer CFL.

The first electrode EL1 may be located on the circuit layer CL. The first electrode EL1 may be conductive and may be electrically connected to the transistor TFT to receive an electrical signal.

The light-emitting layer EML1, EML2, EML3 may be located on the first electrode EL1. For example, a first light-emitting layer EML1 configured to emit red light may be located on the first electrode EL1 of the first light-emitting diode ED1, a second light-emitting layer EML2 configured to emit green light may be located on the first electrode EL1 of the second light-emitting diode ED2, and a third light-emitting layer EML3 configured to emit blue light may be located on the first electrode EL1 of the third light-emitting diode ED3. However, the disclosure is not limited thereto.

The second electrode EL2 may be located on the light-emitting layer EML1, EML2, EML3 and may have an integrated shape extending from the sub-pixel areas SPA1, SPA2, SPA3 to the non-emitting area NPA. The second electrode EL2 may serve as a common electrode.

The encapsulation layer TFE may be located on the display element layer EDL and may be configured to protect the light-emitting diodes ED1, ED2, ED3 of the display element layer EDL from moisture, oxygen, and/or foreign substances. The encapsulation layer TFE may have, but not limited to, a stacked structure in which a first inorganic layer TFE1, an organic layer TFE2, and a second inorganic layer TFE3 are sequentially laminated.

A capping layer may be located between the encapsulation layer TFE and the second electrode EL2. The capping layer may be configured to protect the light-emitting diodes ED1, ED2, ED3 and relatively improve optical characteristics.

The color filter layer CFL may be located on the encapsulation layer TFE. The color filter layer CFL may be directly formed using a deposition process such as a mask-based deposition process, rather than being attached to the encapsulation layer TFE through an adhesive layer.

The color filter layer CFL may include a light-shielding layer BM and color filters CF1, CF2, CF3. The light-shielding layer BM may be located on the encapsulation layer TFE. The light-shielding layer BM may include a light-shielding material. The light-shielding material may include at least one of carbon black, carbon nanotube (CNT), or black dye.

The light-shielding layer BM may be provided with openings OP1, OP2, OP3 that expose the sub-pixel areas SPA1, SPA2, SPA3 in a planar view. For example, the light-shielding layer BM may be provided with first openings OP1 that expose the first sub-pixel areas SPA1 in a planar view, second openings OP2 that expose the second sub-pixel areas SPA2 in a planar view, and third openings OP3 that expose the third sub-pixel areas SPA3 in a planar view.

The light-shielding layer BM may include a base light-shielding layer BM-B, first protruding light-shielding layers BM-P1, second protruding light-shielding layers BM-P2, and third protruding light-shielding layers BM-P3, and may be integrally formed. Each of the first openings OP1 may be defined by the base light-shielding layer BM-B and the first protruding light-shielding layers BM-P1, and each of the second openings OP2 may be defined by the base light-shielding layer BM-B and the second protruding light-shielding layers BM-P2, while each of the third openings OP3 may be defined by the base light-shielding layer BM-B and the third protruding light-shielding layers BM-P3.

The base light-shielding layer BM-B, the first protruding light-shielding layers BM-P1, the second protruding light-shielding layers BM-P2, and the third protruding light-shielding layers BM-P3 may be simultaneously formed using a single mask during the manufacturing process of the display device DD. As a result, the base light-shielding layer BM-B, the first protruding light-shielding layers BM-P1, the second protruding light-shielding layers BM-P2, and the third protruding light-shielding layers BM-P3 may be formed of the same (or substantially the same) material.

The color filters CF1, CF2, CF3 may overlap the openings OP1, OP2, OP3 in a planar view. The color filters CF1, CF2, CF3 may include first color filters CF1, second color filters CF2, and third color filters CF3. The first color filters CF1 may be red filters configured to transmit red light only and may overlap the first openings OP1 in a planar view. The second color filters CF2 may be green filters configured to transmit green light only and may overlap the second openings OP2 in a planar view. The third color filters CF3 may be blue filters configured to transmit blue light only and may overlap the third openings OP3 in a planar view. The color filters CF1, CF2, CF3 may include a polymer photosensitive resin and a pigment or dye.

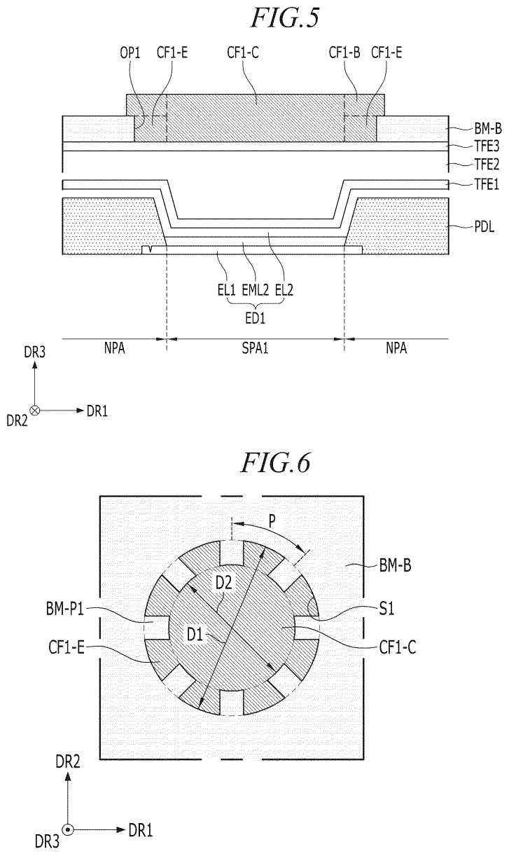

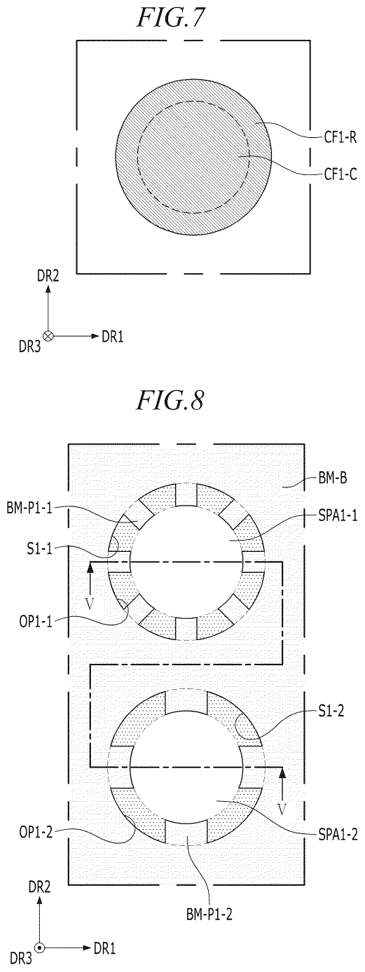

FIG. 4 is an enlarged view of a portion of FIG. 3 that includes the first sub-pixel area. FIG. 5 is a cross-sectional view taken along the line II-II of FIG. 2. FIG. 6 is a cross-sectional view taken along the line III-III of FIG. 4, illustrating the first color filter. FIG. 7 is a cross-sectional view taken along the line IV-IV of FIG. 4, illustrating the second color filter.

In FIGS. 4 and 5, for convenience of illustration, the substrate SUB and the circuit layer CL are omitted. In FIGS. 4 to 7, for clarity, the boundary between the base light-shielding layer BM-B and the first protruding light-shielding layers BM-P1, as well as the boundaries between a central portion CF1-C, extension portions CF1-E, and a cover portion CF1-R of the first color filter CF1, are indicated with dotted lines.

Hereinafter, referring to FIGS. 4 to 7, specific characteristics of the light-shielding layer BM and the color filters CF1, CF2, CF3 will be described, focusing on a first inner surface S1 of the base light-shielding layer BM-B and the first protruding light-shielding layers BM-P1 that define the first opening OP1 and the first color filter CF1 that overlaps the first opening OP1 in a planar view. The following description can also apply to a second inner surface of the base light-shielding layer BM-B and the second protruding light-shielding layers BM-P2 that define the second opening OP2 and the second color filter CF2 that overlaps the second opening OP2 in a planar view, as well as to a third inner surface of the base light-shielding layer BM-B and the third protruding light-shielding layers BM-P3 that define the third opening OP3 and the third color filter CF3 that overlaps the third opening OP3 in a planar view.

Referring to FIGS. 4 to 7, the base light-shielding layer BM-B may include the first inner surface S1, which may define a portion of a boundary of the first opening OP1 in a planar view. The first protruding light-shielding layers BM-P1 may protrude from the first inner surface S1 of the base light-shielding layer BM-B and extend toward the first sub-pixel area SPA1 in a planar view and may define the remaining portion of the boundary of the first opening OP1.

The first inner surface S1 of the base light-shielding layer BM-B may have a circular shape in a planar view. However, the disclosure is not necessarily limited to this configuration, and if the first sub-pixel area SPA1 has an elliptical, rectangular, or polygonal shape in a planar view, the first inner surface S1 may have a corresponding shape.

At least a portion of the first inner surface S1 of the base light-shielding layer BM-B may be spaced apart from the first sub-pixel area SPA1 in a planar view. In some embodiments, the first inner surface S1 of the base light-shielding layer BM-B may be spaced apart from the first sub-pixel area SPA1 in regions in direct contact with the extension portions CF1-E of the first color filter CF1.

Accordingly, the area of the first opening OP1 in a planar view may be greater than the area of the first sub-pixel area SPA1, and a first diameter D1 of the first opening OP1 in the region defined by the first inner surface S1 of the base light-shielding layer BM-B may be greater than a diameter D of the first sub-pixel area SPA1. As a result, variations in optical characteristics due to changes in the viewing angle may be relatively improved. Here, the variations in optical characteristics due to changes in the viewing angle may include issues such as color shifts and luminance reduction due to changes in the viewing angle.

On the contrary, a second diameter D2 of the first opening OP1 in the region defined by the first protruding light-shielding layers BM-P1 may be smaller than the first diameter D1 in a planar view. In some embodiments, the second diameter D2 of the first opening OP1 may be the same (or substantially the same) as the diameter D of the first sub-pixel area SPA1. As a result, issues related to the reflection of external light may be mitigated.

The first protruding light-shielding layers BM-P1 may themselves help relatively improve the issue of diffraction pattern generation.

The first protruding light-shielding layers BM-P1 may be spaced apart from each other along the first inner surface S1 of the base light-shielding layer BM-B in a planar view. In some embodiments, the first protruding light-shielding layers BM-P1 may be arranged at equal (or substantially equal) pitches P along the first inner surface S1 of the base light-shielding layer BM-B in a planar view. In some embodiments, the first protruding light-shielding layers BM-P1 may have the same (or substantially the same) shape and size. However, the disclosure is not necessarily limited to this configuration.

Each of the first protruding light-shielding layers BM-P1 may not overlap the first sub-pixel area SPA1 in a planar view. In some embodiments, each of the first protruding light-shielding layers BM-P1 may extend to the first sub-pixel area SPA1 in a planar view.

The first color filter CF1 may include a central portion CF1-C, extension portions CF1-E, and a cover portion CF1-R and may be integrally formed. The central portion CF1-C of the first color filter CF1 may be located on the encapsulation layer TFE. The central portion CF1-C may overlap the first sub-pixel area SPA1 in a planar view. In some embodiments, the central portion CF1-C and the first sub-pixel area SPA1 may have the same (or substantially the same) shape and size in a planar view.

The extension portions CF1-E of the first color filter CF1 may be located on the encapsulation layer TFE. The extension portions CF1-E may protrude from the central portion CF1-C and extend between the first protruding light-shielding layers BM-P1. That is, the space between an adjacent pair of the first protruding light-shielding layers BM-P1 may be filled by the extension portions CF1-E. As a result, the entire area of the first opening OP1 may be filled with the same material that constitutes the first color filter CF1, thereby achieving relatively uniform display quality.

The extension portions CF1-E may not overlap the first sub-pixel area SPA1 in a planar view. Each of the extension portions CF1-E may extend to the first inner surface S1 of the base light-shielding layer BM-B.

The cover portion CF1-R of the first color filter CF1 may be located on the extension portions CF1-E. The cover portion CF1-R may cover the extension portions CF1-E and the first protruding light-shielding layers BM-P1 in a planar view and may overlap a portion of the base light-shielding layer BM-B in a planar view. The cover portion CF1-R may have a ring shape surrounding the central portion CF1-C in a planar view.

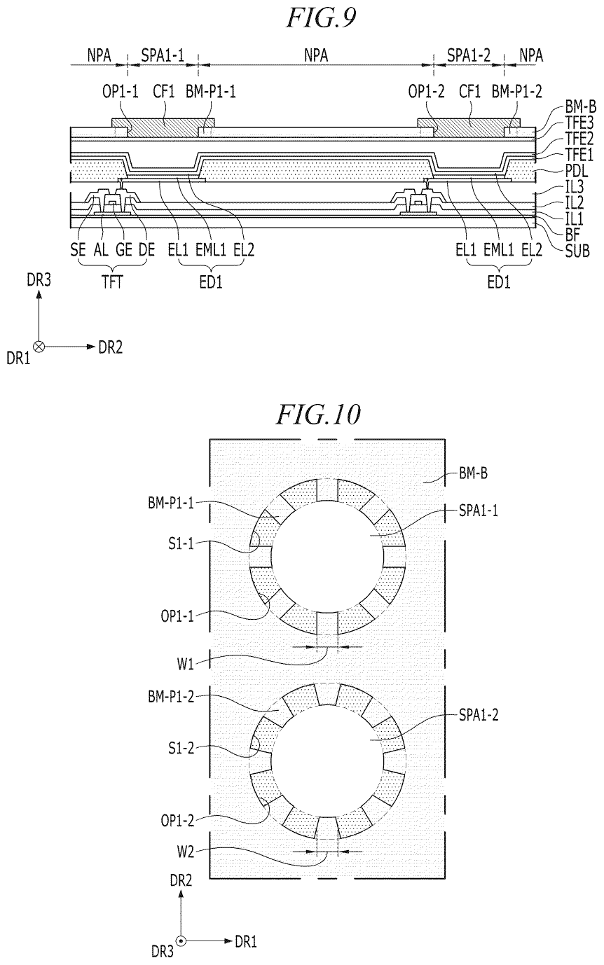

FIG. 8 is an enlarged view of the first sub-pixel areas of FIG. 1, and FIG. 9 is a cross-sectional view taken along the line V-V of FIG. 8. In FIG. 8, for clarity, the first color filters CF1 of FIG. 9 are omitted, and the boundaries of the light-emitting areas SPA1-1, SPA1-2, as well as the boundary between the base light-shielding layer BM-B and sub-protruding light-shielding layers BM-P1-1, BM-P1-2, are indicated with dotted lines.

Referring to FIGS. 8 and 9, the first sub-pixel areas SPA1 may include a first light-emitting area SPA1-1 and a second light-emitting area SPA1-2. The first light-emitting area SPA1-1 may be one of the first sub-pixel areas SPA1, and the second light-emitting area SPA1-2 may be another one of the first sub-pixel areas SPA1. The first light-emitting area SPA1-1 and the second light-emitting area SPA1-2 may be configured to display light having the same (or substantially the same) wavelength range. In some embodiments, the first light-emitting area SPA1-1 and the second light-emitting area SPA1-2 may each include, but not limited to, a first light-emitting diode ED1 that is configured to emit red light.

The first light-emitting area SPA1-1 and the second light-emitting area SPA1-2 may have the same (or substantially the same) area in a planar view (or a plan view). In a planar view (or a plan view), the first light-emitting area SPA1-1 may be exposed through a first sub-opening OP1-1 provided in the light-shielding layer BM. The first sub-opening OP1-1 may be one of the first openings OP1. In a planar view (or a plan view), the second light-emitting area SPA1-2 may be exposed through a second sub-opening OP1-2 provided in the light-shielding layer BM. The second sub-opening OP1-2 may be another one of the first openings OP1.

The first sub-opening OP1-1 may be defined by a first sub-inner surface S1-1 of the base light-shielding layer BM-B and first sub-protruding light-shielding layers BM-P1-1 in a planar view (or a plan view). The first sub-inner surface S1-1 may define a portion of the boundary of the first sub-opening OP1-1 in a planar view (or a plan view). The first sub-protruding light-shielding layers BM-P1-1 may protrude from the first sub-inner surface S1-1 of the base light-shielding layer BM-B and extend toward the first light-emitting area SPA1-1 in a planar view (or a plan view) and may define the remaining portion of the boundary of the first sub-opening OP1-1.

The second sub-opening OP1-2 may be defined by a second sub-inner surface S1-2 of the base light-shielding layer BM-B and second sub-protruding light-shielding layers BM-P1-2 in a planar view (or a plan view). The second sub-inner surface S1-2 may define a portion of the boundary of the second sub-opening OP1-2 in a planar view (or a plan view). The second sub-protruding light-shielding layers BM-P1-2 may protrude from the second sub-inner surface S1-2 of the base light-shielding layer BM-B and extend toward the second light-emitting area SPA1-2 in a planar view (or a plan view) and may define the remaining portion of the boundary of the second sub-opening OP1-2.

The first sub-inner surface S1-1 and the second sub-inner surface S1-2 may each be one of the first inner surfaces S1, and the descriptions provided above for the first inner surfaces S1 may also be applied to the first sub-inner surface S1-1 and the second sub-inner surface S1-2. Similarly, the first sub-protruding light-shielding layers BM-P1-1 and the second sub-protruding light-shielding layers BM-P1-2 may each be a portion of the first protruding light-shielding layers BM-P1, and the descriptions provided above for the first protruding light-shielding layers BM-P1 may also be applied to the first sub-protruding light-shielding layers BM-P1-1 and the second sub-protruding light-shielding layers BM-P1-2.

The first sub-opening OP1-1 and the second sub-opening OP1-2 may have the same (or substantially the same) area in a planar view (or a plan view). In some embodiments, the circular area defined by the first sub-inner surface S1-1 of the base light-shielding layer BM-B and the circular area defined by the second sub-inner surface S1-2 of the base light-shielding layer BM-B may have the same (or substantially the same) area in a planar view (or a plan view), and the aggregated area of the first sub-protruding light-shielding layers BM-P1-1 and the aggregated area of the second sub-protruding light-shielding layers BM-P1-2 may be the same (or substantially the same) in a planar view (or a plan view). Moreover, at least one of the number, size, or shape of the first sub-protruding light-shielding layers BM-P1-1 and the second sub-protruding light-shielding layers BM-P1-2 may be different from each other. As a result, relatively uniform optical characteristics can be ensured across the entire display area, while the issue of diffraction pattern generation may be mitigated.

According to some embodiments, the number of first sub-protruding light-shielding layers BM-P1-1 and the number of second sub-protruding light-shielding layers BM-P1-2 may be different from each other. As shown in the drawing, the number of first sub-protruding light-shielding layers BM-P1-1 may be eight, whereas the number of second sub-protruding light-shielding layers BM-P1-2 may be four, but these numbers are not limited to the illustration in the drawing. In this case, to ensure that the first sub-opening OP1-1 and the second sub-opening OP1-2 have the same (or substantially the same) area in a planar view (or a plan view), the size (e.g., width or area) of each of the second sub-protruding light-shielding layers BM-P1-2 may be greater than the size (e.g., width or area) of each of the first sub-protruding light-shielding layers BM-P1-1, as can be confirmed from the drawing.

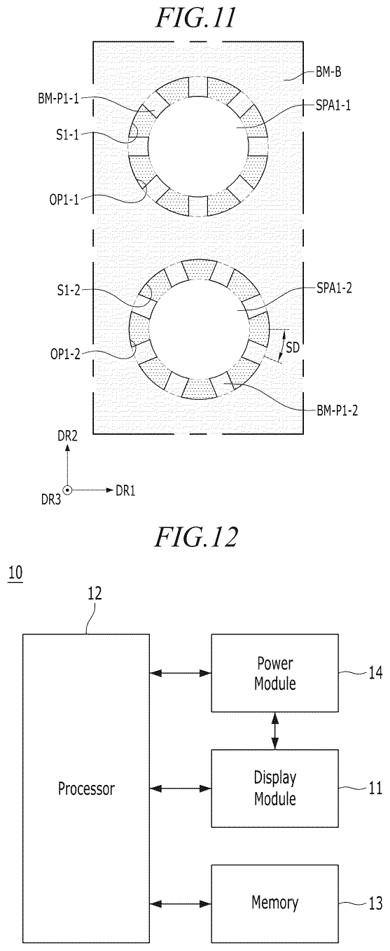

FIG. 10 illustrates a modified example of FIG. 8. Referring to FIG. 10, the shape of each of the first sub-protruding light-shielding layers BM-P1-1 may be different from the shape of each of the second sub-protruding light-shielding layers BM-P1-2. In this modified example, as shown in the drawing, each of the first sub-protruding light-shielding layers BM-P1-1 may have a shape similar to or identical to a rectangle, with the width W1 in a direction perpendicular to the radial direction of the first sub-opening OP1-1 remaining constant along the radial direction. On the contrary, each of the second sub-protruding light-shielding layers BM-P1-2 may have a shape similar to or identical to a trapezoid, with the width W2 in a direction perpendicular to the radial direction of the second sub-opening OP1-2 increasing nearer the second sub-inner surface S1-2. However, the present disclosure is not limited to this configuration.

FIG. 11 illustrates another modified example of FIG. 8. Referring to FIG. 11, the positions where the first sub-protruding light-shielding layers BM-P1-1 are connected to the first sub-inner surface S1-1 of the base light-shielding layer BM-B may differ from the positions where the second sub-protruding light-shielding layers BM-P1-2 are connected to the second sub-inner surface S1-2 of the base light-shielding layer BM-B.

In some embodiments, the positions where the second sub-protruding light-shielding layers BM-P1-2 are connected to the second sub-inner surface S1-2 of the base light-shielding layer BM-B may be offset by a shift distance SD along the second sub-inner surface S1-2 relative to the corresponding positions where the first sub-protruding light-shielding layers BM-P1-1 are connected to the first sub-inner surface S1-1 of the base light-shielding layer BM-B. Here, the shift distance SD may be smaller than the pitch P of the first protruding light-shielding layers BM-P1.

In this modified example, the first sub-opening OP1-1 and the second sub-opening OP1-2 may have the same (or substantially the same) area in a planar view (or a plan view). As a result, relatively uniform optical characteristics may be ensured across the entire display area, and the issue of diffraction pattern generation may be relatively improved.

In this modified example, the number, size, and shape of the first sub-protruding light-shielding layers BM-P1-1 and the second sub-protruding light-shielding layers BM-P1-2 may be the same (or substantially the same). However, the present disclosure is not limited to this configuration.

In certain embodiments of the present disclosure, the first sub-opening OP1-1 and the second sub-opening OP1-2 may have the same (or substantially the same) area in a planar view (or a plan view). The first sub-protruding light-shielding layers BM-P1-1 and the second sub-protruding light-shielding layers BM-P1-2 may not be perfectly aligned with each other when shifted along the first direction DR1 and/or the second direction DR2 in a planar view (or a plan view).

In the above descriptions, the area relationship of the first sub-opening OP1-1 and the second sub-opening OP1-2, as well as the number, size, shape, and arrangement of the first sub-protruding light-shielding layers BM-P1-1 and the second sub-protruding light-shielding layers BM-P1-2, have been described based on drawings in which the first light-emitting area SPA1-1 and the second light-emitting area SPA1-2 are circular in a planar view (or a plan view). However, even if the first light-emitting area SPA1-1 and the second light-emitting area SPA1-2 are not circular, such as being rectangular, the same principles may apply.

Moreover, the descriptions above may also equally apply regarding the area relationship of the first opening OP1 and the second opening OP2 or third opening OP3, as well as the number, size, shape, and arrangement of the first protruding light-shielding layers BM-P1 and the second protruding light-shielding layers BM-P2 or third protruding light-shielding layers BM-P3.

The display device DD according to embodiments of the present disclosure may be applied to various electronic apparatuses. An electronic apparatus according to some embodiments of the present disclosure includes the display device DD described above and may further include additional functional modules or components besides the display device DD.

FIG. 12 is a block diagram of an electronic apparatus according to some embodiments of the present disclosure. Referring to FIG. 12, an electronic apparatus 10 according to some embodiments of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may have data and information necessary for the operation of the processor 12 or the display module 11 stored therein. When the processor 12 executes an application stored in the memory 13, video data signals and/or input control signals may be transferred to the display module 11, which may be configured to process the received signals and output image information through a display screen.

The power module 14 may include a power supply module, such as a power adapter or a battery device, and a power conversion module configured to convert the power supplied by the power supply module to generate power required for the operation of the electronic apparatus 10.

At least one of the components of the electronic apparatus 10 described above may be included within the display device DD according to the embodiments described above. Moreover, some of the individual modules functionally included within a single module may be partially integrated into the display device DD, while others may be separately provided outside the display device DD. For example, the display device DD may include the display module 11, while the processor 12, the memory 13, and the power module 14 may be provided as separate components within the electronic apparatus 10 rather than being integrated into the display device DD.

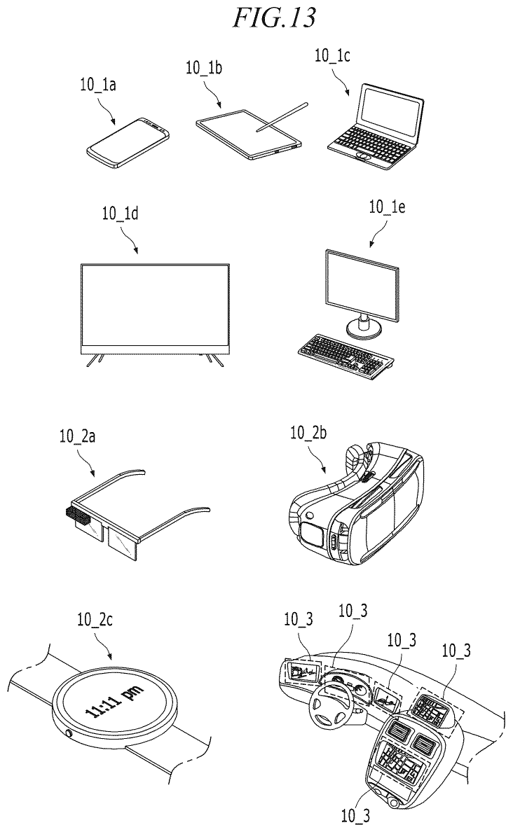

FIG. 13 illustrates various electronic apparatuses according to different embodiments. Referring to FIG. 13, various electronic apparatuses 10 incorporating the display device DD according to embodiments of the present disclosure may include not only image display electronic apparatuses such as a smartphone 10_1a, a tablet PC 10_1b, a laptop computer 10_1c, a TV 10_1d, and a desktop monitor 10_1e, but also wearable electronic apparatuses including a display module, such as smart glasses 10_2a, a head-mounted display 10_2b, and a smartwatch 10_2c. Additionally, the display device DD may be applied to automotive electronic apparatuses 10_3 including a display module, such as an instrument panel, a center information display (CID) positioned in a vehicle's center fascia or dashboard, and a rear-view mirror display.

Although aspects of some embodiments of the present disclosure have been described above, these are merely examples and are not intended to limit the scope of embodiments according to the present disclosure. Those skilled in the art to which the present disclosure pertains may make various modifications and changes to the embodiments by adding, changing, deleting, or adding certain elements, without departing from the scope of the technical ideas of the present disclosure as set forth in the claims, and such modifications and changes should also be regarded as being within the scope of the present disclosure.

What is claimed is:

1. A display device, comprising:
a substrate;
a transistor on the substrate;
a pixel defining layer on the transistor and exposing a sub-pixel area where light is displayed; and
a color filter layer on the pixel defining layer,
wherein the color filter layer comprises:
a light-shielding layer having an opening that exposes the sub-pixel area in a plan view; and
a color filter overlapping the opening in the plan view,
wherein the light-shielding layer comprises:
a base light-shielding layer having an inner surface that defines a portion of a boundary of the opening in the plan view; and
protruding light-shielding layers protruding from the inner surface of the base light-shielding layer and extending toward the sub-pixel area and defining a remaining portion of the boundary of the opening in the plan view,
wherein the color filter comprises:
a central portion overlapping the sub-pixel area in the plan view; and
extension portions protruding from the central portion and extending between the protruding light-shielding layers and not overlapping the sub-pixel area in the plan view.

2. The display device of claim 1, wherein the area of the opening in the plan view is greater than the area of the sub-pixel area.

3. The display device of claim 1, wherein the inner surface of the base light-shielding layer is spaced apart from the sub-pixel area in the plan view, and
wherein each of the extension portions extends to the inner surface of the base light-shielding layer.

4. The display device of claim 1, wherein the protruding light-shielding layers are spaced apart from each other along the inner surface of the base light-shielding layer in the plan view.

5. The display device of claim 1, wherein the protruding light-shielding layers are arranged at equal pitches along the inner surface of the base light-shielding layer in the plan view.

6. The display device of claim 1, wherein the protruding light-shielding layers have a same shape and size in the plan view.

7. The display device of claim 1, wherein each of the protruding light-shielding layers does not overlap the sub-pixel area in the plan view.

8. The display device of claim 1, wherein each of the protruding light-shielding layers extends to the sub-pixel area in the plan view.

9. The display device of claim 1, wherein the pixel defining layer comprises a light-shielding material.

10. The display device of claim 9, wherein the light-shielding material comprises at least one of carbon black, carbon nanotube (CNT), or black dye.

11. The display device of claim 1, wherein the sub-pixel area comprises first sub-pixel areas configured to display light having a same wavelength range, and
wherein the opening comprises:
a first sub-opening exposing a first light-emitting area, which is one of the first sub-pixel areas, in the plan view; and
a second sub-opening exposing a second light-emitting area, which is another one of the first sub-pixel areas, in the plan view, and
wherein the first sub-opening and the second sub-opening have a same area in the plan view.

12. The display device of claim 11, wherein the inner surface of the base light-shielding layer comprises:
a first sub-inner surface defining a portion of a boundary of the first sub-opening in the plan view; and
a second sub-inner surface defining a portion of a boundary of the second sub-opening in the plan view, and
wherein the protruding light-shielding layers comprise:
first sub-protruding light-shielding layers protruding from the first sub-inner surface of the base light-shielding layer and extending toward the first light-emitting area in the plan view, the first sub-protruding light-shielding layers defining the remaining portion of the boundary of the first sub-opening in the plan view; and
second sub-protruding light-shielding layers protruding from the second sub-inner surface of the base light-shielding layer and extending toward the second light-emitting area in the plan view, the second sub-protruding light-shielding layers defining the remaining portion of the boundary of the second sub-opening in the plan view.

13. The display device of claim 12, wherein the number of the first sub-protruding light-shielding layers is different from the number of the second sub-protruding light-shielding layers.

14. The display device of claim 12, wherein the first sub-protruding light-shielding layers and the second sub-protruding light-shielding layers have different sizes.

15. The display device of claim 12, wherein the first sub-protruding light-shielding layers and the second sub-protruding light-shielding layers have different shapes.

16. A display device, comprising:
a substrate;
a transistor on the substrate;
a pixel defining layer on the transistor and exposing first sub-pixel areas, each of which is configured to display light having a first wavelength range; and
a color filter layer on the pixel defining layer,
wherein the color filter layer comprises a light-shielding layer being provided with a first sub-opening exposing a first light-emitting area, which is one of the first sub-pixel areas, in a plan view, and a second sub-opening exposing a second light-emitting area, which is another one of the first sub-pixel areas, in the plan view,
wherein the light-shielding layer comprises:
a base light-shielding layer comprising a first sub-inner surface defining a portion of a boundary of the first sub-opening in the plan view and a second sub-inner surface defining a portion of a boundary of the second sub-opening in the plan view;
first sub-protruding light-shielding layers protruding from the first sub-inner surface of the base light-shielding layer and extending toward the first light-emitting area, the first sub-protruding light-shielding layers defining the remaining portion of the boundary of the first sub-opening in the plan view; and
second sub-protruding light-shielding layers protruding from the second sub-inner surface of the base light-shielding layer and extending toward the second light-emitting area, the second sub-protruding light-shielding layers defining the remaining portion of the boundary of the second sub-opening in the plan view,
wherein the first sub-opening and the second sub-opening have a same area in the plan view, and
wherein at least one of the number, size, or shape of the first sub-protruding light-shielding layers is different from that of the second sub-protruding light-shielding layers.

17. The display device of claim 16, wherein the area of the first sub-opening of the base light-shielding layer is greater than the area of the first light-emitting area in the plan view, and
wherein the area of the second sub-opening of the base light-shielding layer is greater than the area of the second light-emitting area in the plan view.

18. The display device of claim 16, wherein the first sub-inner surface of the base light-shielding layer is spaced apart from the first light-emitting area in the plan view,
wherein the second sub-inner surface of the base light-shielding layer is spaced apart from the second light-emitting area in the plan view,
wherein each of the first sub-protruding light-shielding layers extends to the first light-emitting area in the plan view, and
wherein each of the second sub-protruding light-shielding layers extends to the second light-emitting area in the plan view.

19. An electronic apparatus comprising a display device,
wherein the display device comprises:
a substrate;
a transistor on the substrate;
a pixel defining layer on the transistor and exposing a sub-pixel area where light is displayed; and
a color filter layer on the pixel defining layer,
wherein the color filter layer includes:
a light-shielding layer having an opening that exposes the sub-pixel area in a plan view; and
a color filter overlapping the opening in the plan view,
wherein the light-shielding layer comprises:
a base light-shielding layer comprising an inner surface that defines a portion of a boundary of the opening in the plan view; and
protruding light-shielding layers protruding from the inner surface of the base light-shielding layer and extending toward the sub-pixel area and defining the remaining portion of the boundary of the opening in the plan view,
wherein the color filter comprises:
a central portion overlapping the sub-pixel area in the plan view; and
extension portions protruding from the central portion and extending between the protruding light-shielding layers, the extension portions not overlapping the sub-pixel area in the plan view.

20. The electronic apparatus of claim 19, further comprising:
a processor configured to control the display device;
a memory configured to store data required for operation of the display device or the processor; and
a power module configured to generate or supply power.
